(19) United States
(12) Patent Application Publication
(10) Pub. No.: US 2025/0254948 A1
(43) Pub. Date: Aug. 7, 2025

(54) HIGH ELECTRON MOBILITY TRANSISTOR AND MANUFACTURING METHOD THEREOF

(71) Applicant: HiPer Semiconductor Inc., Cayman Islands (KY)

(72) Inventors: WEI-CHIH HO, Zhubei City (TW); PO-JUNG LIN, Zhubei City (TW)

(21) Appl. No.: 18/970,264

(22) Filed: Dec. 5, 2024

(30) Foreign Application Priority Data
Feb. 7, 2024 (TW) 113104958

(51) Int. Cl. H10D 62/17; H10D 30/01; H10D 30/47; H10D 62/824

(52) U.S. Cl. CPC H10D 62/343; H10D 30/015; H10D 30/475; H10D 62/824

(57) ABSTRACT

A high electron mobility transistor and a method for manufacturing the same are disclosed. The high electron mobility transistor includes an epi layer, a source, a drain, a gate structure and a gate metal. The source, the gate structure and the drain locate on the epi layer. The gate structure is located between the source and the drain. The gate structure includes a first doped semiconductor layer with a first width W1, a current suppression layer with a third width W3, and a second doped semiconductor layer with a first width W2, wherein W1>W2, W3=W2. The first doped semiconductor layer is disposed on the epi layer. The current suppression layer is disposed on the first doped semiconductor layer. The second doped semiconductor layer is disposed on the current suppression layer. The gate metal is disposed on the second doped semiconductor layer.

### BACKGROUND

### 1. Technical Field

The present disclosure relates to a high electron mobility transistor (HEMT), and more particularly to a high electron mobility transistor and its manufacturing method that uses a current suppression layer to control the etching depth of the gate structure and improve gate leakage current.

### 2. Description of the Related Art

As disclosed in U.S. Patent Publication No. U.S. Pat. No. 7,663,161, the gate structure of an enhancement-mode (E-mode) high electron mobility transistor (HEMT) with a p-type doped gallium nitride (GaN) layer can be etched into a stepped structure to suppress gate leakage current. However, since the stepped etching of the gate structure must involve both the horizontal directions (x-direction, y-direction) and the depth direction (z-direction), U.S. Patent No. U.S. Pat. No. 7,663,161 only discloses the alignment technique for etching in the horizontal directions (x-direction, y-direction) and does not disclose a technique for accurately controlling the gate depth direction (z-direction). In practical operations, when etching the gate structure to form a stepped shape, it is necessary to calculate the etching time for each step to control the depth (Z-direction) of the gate structure. However, due to limitations in the processing equipment, the current approach relies on time estimation to control the gate etching depth. This results in an inability to precisely control the depth (Z-direction) of each step in the gate structure, often leading to a suboptimal etched shape. Consequently, the effectiveness of suppressing gate leakage current is significantly reduced, highlighting the need for improvement.

### SUMMARY

The objective of the present disclosure is to provide a high electron mobility transistor (HEMT) that uses a current suppression layer to control gate etching depth and reduce gate leakage current.

Another objective of the present disclosure is to provide a method for manufacturing a high electron mobility transistor (HEMT) that uses a current suppression layer to control gate etching depth and reduce gate leakage current.

To achieve the above objectives, the high electron mobility transistor (HEMT) of the present disclosure includes an epitaxial layer (epi layer), a source, a drain, a gate structure, and a gate metal. The source, the gate structure, and the drain are all positioned on the epitaxial layer. The gate structure is located between the source and the drain. The gate structure includes a first doped semiconductor layer, a current suppression layer, and a second doped semiconductor layer. The first doped semiconductor layer is disposed on the epi layer, the current suppression layer is disposed on the first doped semiconductor layer, and the second doped semiconductor layer is disposed on the current suppression layer. The gate metal is disposed on the second doped semiconductor layer. The first doped semiconductor layer has a first width (W1), the second doped semiconductor layer has a second width (W2), and the current suppression layer has a third width (W3), with W1>W2, W3=W2.

The present disclosure further provides an embodiment of a high electron mobility transistor manufacturing method, which includes following steps: deposing a first doped semiconductor epi layer on an epitaxial layer; deposing a current suppression layer on the first doped semiconductor epi layer; deposing a second doped semiconductor epi layer on the current suppression layer; defining a gate metal on the second doped semiconductor epi layer; placing two first spacers on opposite sides of the gate metal; etching the second doped semiconductor epi layer that is not covered by the gate metal and the two first spacers to form a second doped semiconductor layer; placing two second spacers on opposite sides of the second doped semiconductor layer; and etching the first doped semiconductor epi layer that is not covered by the second doped semiconductor layer and the two second spacers, thereby forming a gate structurer on the epitaxial layer that includes a first doped semiconductor layer, the current suppression layer and the second doped semiconductor layer. The first doped semiconductor layer has a first width (W1), the second doped semiconductor layer has a second width (W2), and the current suppression layer has a third width (W3), wherein W1>W2, W3=W2.

The present disclosure further provides another embodiment of a high electron mobility transistor manufacturing method, which includes following steps: deposing a first doped semiconductor epi layer on an epitaxial layer; deposing a current suppression layer on the first doped semiconductor epi layer; deposing a second doped semiconductor epi layer on the current suppression layer; defining a width of a second doped semiconductor layer using a mask on the second doped semiconductor epi layer; etching the second doped semiconductor epi layer to form a second doped semiconductor layer; placing two first spacers on opposite sides of the second doped semiconductor layer; and etching the first doped semiconductor epi layer that is not covered by the second doped semiconductor layer and the two first spacers, thereby forming a gate structure on the epitaxial layer that includes a first doped semiconductor layer, the current suppression layer, and the second doped semiconductor layer. The first doped semiconductor layer has a first width (W1), the second doped semiconductor layer has a second width (W2), and the current suppression layer has a third width (W3), wherein W1>W2, W3=W2.

By incorporating a current suppression layer between the first doped semiconductor layer and the second doped semiconductor layer in the gate structure of the high electron mobility transistor (HEMT) of the present disclosure, gate leakage current flowing vertically from the gate metal towards the second doped semiconductor layer, the current suppression layer, and the first doped semiconductor layer can be effectively reduced. Additionally, the current suppression layer can also serve as an etching stop layer, thereby controlling the etching depth (Z-direction) of both the first doped semiconductor layer and the second doped semiconductor layer in the gate structure. This extends the path of the gate leakage current (Ig), further reducing it. This approach addresses the issues found in prior art, where controlling the etch depth of the gate structure was challenging, resulting in suboptimal gate structure shapes and ineffective gate leakage current suppression.

### BRIEF DESCRIPTION OF THE DRAWINGS

FIG. 1A is a schematic diagram of a first embodiment of the high electron mobility transistor (HEMT) of the present disclosure;

FIG. 1B is a schematic diagram of a second embodiment of the high electron mobility transistor (HEMT) of the present disclosure;

FIG. 1C is a schematic diagram of a third embodiment of the high electron mobility transistor (HEMT) of the present disclosure;

FIG. 1D is a schematic diagram of a fourth embodiment of the high electron mobility transistor (HEMT) of the present disclosure;

FIG. 2 is a flowchart illustrating the steps of the first embodiment of the high electron mobility transistor manufacturing method of the present disclosure;

FIG. 3A to FIG. 3E are schematic diagrams illustrating the process flow of the first embodiment of the high electron mobility transistor manufacturing method of the present disclosure;

FIG. 4 is a flowchart illustrating the steps of the second embodiment of the high electron mobility transistor manufacturing method of the present disclosure;

FIG. 5A to FIG. 5E are schematic diagrams illustrating the process flow of the second embodiment of the high electron mobility transistor manufacturing method of the present disclosure;

FIG. 6 is a schematic diagram combining the first embodiment of the gate structure of the present disclosure with the second embodiment of the gate metal; and

FIG. 7 is a schematic diagram combining the fifth embodiment of the gate structure of the present disclosure with the second embodiment of the gate metal.

### DETAILED DESCRIPTION OF THE EMBODIMENTS

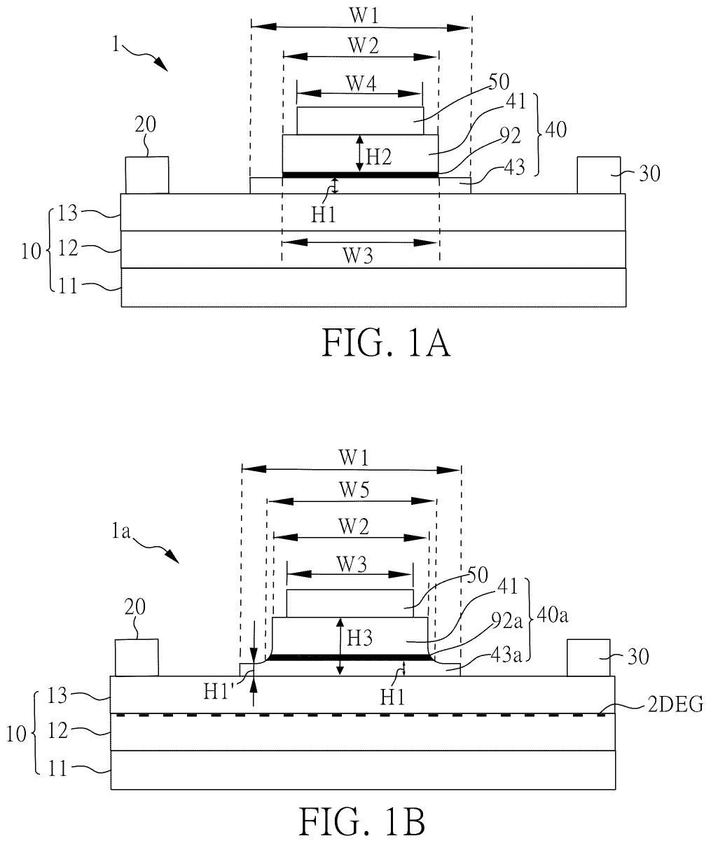

In order to make the structure and characteristics as well as the effectiveness of the present disclosure further understood and recognized, a detailed description of the present disclosure is provided as follows, along with embodiments and accompanying figures. Please refer to FIG. 1A and FIG. 1B relate to schematic diagrams of the first embodiment and the second embodiment of the high electron mobility transistor (HEMT) of the present disclosure.

As shown in FIG. 1A, in the first embodiment, the high electron mobility transistor of the present disclosure includes an epitaxial layer 10, a source 20, a drain 30, a gate structure 40 and a gate metal 50. The source 20, the drain 30, and the gate structure 40 are disposed on the epitaxial layer 10. The gate structure 40 is located between the source 20 and the drain 30. The gate structure 40 includes a first doped semiconductor layer 43, a current suppression layer 92, and a second doped semiconductor layer 41. The gate metal 50 is disposed on the second doped semiconductor layer 41. The second doped semiconductor layer 41 is disposed on the current suppression layer 92, and the first doped semiconductor layer 43 is disposed on the epitaxial layer 10. In other words, the current suppression layer 92 is positioned between the first doped semiconductor layer 43 and the second doped semiconductor layer 41, with the first doped semiconductor layer 43 located underneath the second doped semiconductor layer 41. Furthermore, the first doped semiconductor layer 43 has a first width (W1), the second doped semiconductor layer 41 has a second width (W2), and the current suppression layer 92 has a third width (W3), wherein W1>W2, W3=W2.

By incorporating the current suppression layer 92, the gate leakage current (Ig) that flows vertically from the gate metal 50 towards the second doped semiconductor layer 41, the current suppression layer 92, and the first doped semiconductor layer 43 can be effectively reduced. Additionally, the etching depth of the second doped semiconductor layer 41 can be precisely controlled to stop at the current suppression layer 92. In this embodiment, the high electron mobility transistor (HEMT) 1 is an enhancement-mode (E-mode) HEMT. The epitaxial layer 10 includes a substrate 11, a channel layer 12, and a barrier layer 13. The substrate 11 can be made of silicon, sapphire, SiC, diamond, or other composite materials such as silicon on insulator (SOI) substrate or a QST substrate. The channel layer 12 is gallium nitride (GaN). The barrier layer 13 can be made of an aluminum gallium nitride (Al_{y}Ga_{1-y}N) structure. The gate structure 40 is a p-type GaN structure, with a p-type dopant material such as magnesium (Mg). The material of the second doped semiconductor layer 41 can be p-type GaN, and the material of the current suppression layer 92 can be aluminum gallium nitride (AlGaN), a GaN heterostructure (Al_{X}Ga_{1-X}N, where 0.4≤X≤1), or it can be doped with p-type, n-type, or is undoped (i-type) atoms. In the preferred embodiment of the present disclosure, the current suppression layer 92 is doped with p-type material, and the thickness of the current suppression layer 92 ranges from 0.5 nm to 5 nm. The first doped semiconductor layer 43 can be p-type gallium nitride (GaN), and the gate metal layer 50 can be titanium nitride (TiN), disposed on top of the second doped semiconductor layer 41.

In this embodiment, the gate structure 40 has a two-step stepped structure, wherein both the first doped semiconductor layer 43 and the second doped semiconductor layer 41 are substantially rectangular. The two opposite sides of the gate structure 40 both exhibit a stepped structure. At the same time, as shown in FIG. 1A, the current suppression layer 92 is located beneath the second doped semiconductor layer 41, and the first doped semiconductor layer 43 exposed by the second doped semiconductor layer 41 does not have any remaining the current suppression layer 92. In this embodiment, the gate metal 50 has a fourth width (W4), wherein the second width (W2) of the second doped semiconductor layer 41 is greater than the fourth width (W4). In other embodiments, the second width (W2) can be designed to be equal to the fourth width (W4).

As shown in FIG. 1A, in the first embodiment, the first doped semiconductor layer 43 has a first step height (H1), and the second doped semiconductor layer 41 has a second step height (H2), where H2>H1. It is noted that, the second step height H2 refers to the distance from the second doped semiconductor layer 41 to the upper surface of the current suppression layer 92, while the first step height H1 refers to the distance from the lower surface of the current suppression layer 92 to the first doped semiconductor layer 43, with H2>H1. The range of the second step height (H2) of the present disclosure is between 65 nm to 80 nm. Further, since the current suppression layer 92 of the present disclosure also controls the etching depth, the thickness of the first doped semiconductor layer (H1) of the present disclosure can be less than 10 nm. However, the present disclosure is not limited to this embodiment, and the range for the first step height (H1) is between 5 nm to 20 nm. According to one embodiment of the present disclosure, the thickness ratio of the second step height (H2) to the first step height (H1) is 13:4.

As shown in FIG. 1B, the gate structure 40a in the second embodiment is the same as the gate structure 40 in the first embodiment, with both having a two-step stepped structure. The first doped semiconductor layer 43 of the gate structure 40a in the second embodiment has a fifth width (W5), wherein W1>W5. In addition, as shown in FIG. 1A and FIG. 1B, the gate structure 40a has a gate height (H3), where H3≤120 nm. This gate height (H3) includes the second step height (H2), the thickness of the current suppression layer, and the first step height (H1). In the second embodiment of the gate structure 40a, the height of the first doped semiconductor layer 43 covered by the current suppression layer 92 is referred to as the first step height H1, while the height of the first doped semiconductor layer 43 not covered by the current suppression layer 92 is referred to as the first step height H1′, where H1>H1′. In this embodiment, the first doped semiconductor layer 43 has a fifth width (W5), which represents the width of the portion beneath and covered by the current suppression layer 92. The reasons the first doped semiconductor layer 43 exhibits both a first width (W1) and a fifth width (W5), as well as the first step heights H1 and H1′, are as follows: as shown in FIG. 1B, the height of the first doped semiconductor layer 43 that is not covered by the current suppression layer 92 is over-etched, reducing it to H1′. As shown in FIG. 1B, although the etching process may remove a portion of the current suppression layer 92 and a part of the first doped semiconductor layer 43, the height of the portion of the first doped semiconductor layer 43 beneath the current suppression layer 92 remains at the originally designed height, H1. Therefore, H1>H1′ and W1>W5.

Please refer to FIG. 1A and FIG. 1B, and also refer to FIG. 1C related to a schematic diagram of the gate structure of the third embodiment of the high electron mobility transistor (HEMT) of the present disclosure.

As shown in FIG. 1C, in the third embodiment, the gate structure 40b has the same two-step stepped structure as in the previous two embodiments. However, in the third embodiment, the stepped gate structure 40b features a single-sided stepped structure. Specifically, the second short axis side 411 of the second doped semiconductor layer 41 is vertically aligned with the first short axis side 431 of the first doped semiconductor layer 43. It is noted that, as shown in FIG. 1A to FIG. 1C, the gate structure 40, 40a, 40b in the first to third embodiments, including the second doped semiconductor layer 41 and the first doped semiconductor layer 43, 43a, are all rectangular. In other words, each step of the gate structure 40, 40a, 40b presents a standard stepped profile, with step surfaces and step walls being perpendicular.

Additionally, the current suppression layer 92, 92a, and 92b located between the first doped semiconductor layer 43 and the second doped semiconductor layer 41, can improve the process tolerance of the gate structure 40, 40a, and 40b. For example, they allow for adjustments to the second step height H2 of the second doped semiconductor layer 41 or the first step height H1 of the first doped semiconductor layer 43 according to design requirements. During etching, the current suppression layer 92, 92a, and 92b are employed to precisely control the etching depth in the vertical direction (Z-direction) of both the second doped semiconductor layer 41 and the first doped semiconductor layer 43, 43a. This enables the formation of an ultra-thin first doped semiconductor layer 43, with a first step height H1 less than 10 nm. For example, as shown in FIG. 1A, during the etching of the gate structure 40, the first step height H1 is controlled to be less than the second step height H2. Alternatively, as shown in FIG. 1C, during the etching of the gate structure 40b, the second step height H2 is controlled to be equal to the first step height H1. This approach addresses the issue of controlling the etching depth of the gate structure, which was difficult to manage in prior art.

Please refer to FIG. 1C and also refer to FIG. 1D for a schematic diagram of the gate structure of the fourth embodiment of the high electron mobility transistor of the present disclosure.

As shown in FIG. 1D, in the fourth embodiment, both the second doped semiconductor layer 41a and the first doped semiconductor layer 43b have a trapezoidal shape, with a narrower top surface and a wider bottom surface. The first doped semiconductor layer 43b includes a first platform 432, and the second doped semiconductor layer 41a includes a second platform 412, where the width of the second platform 412 is less than or equal to the width of the first platform 432.

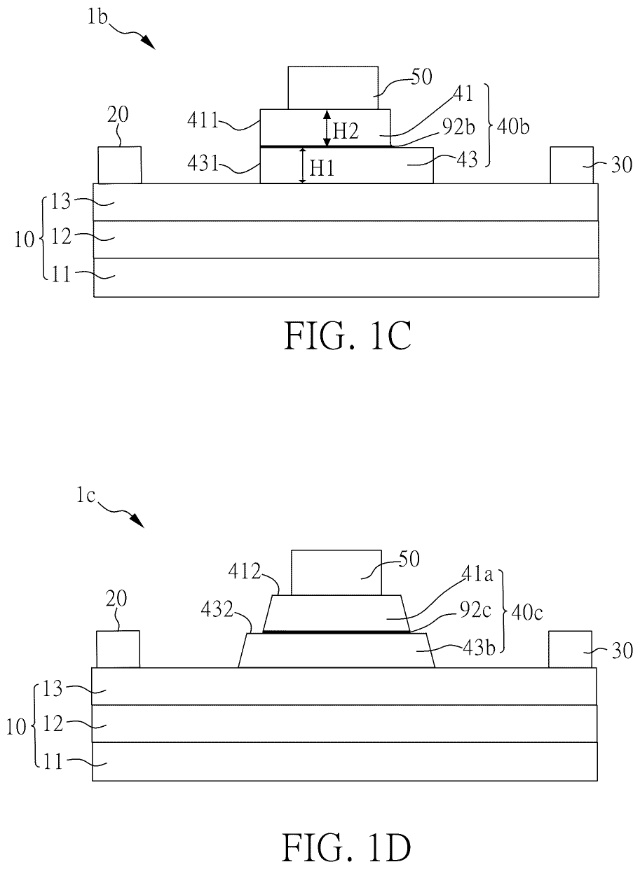

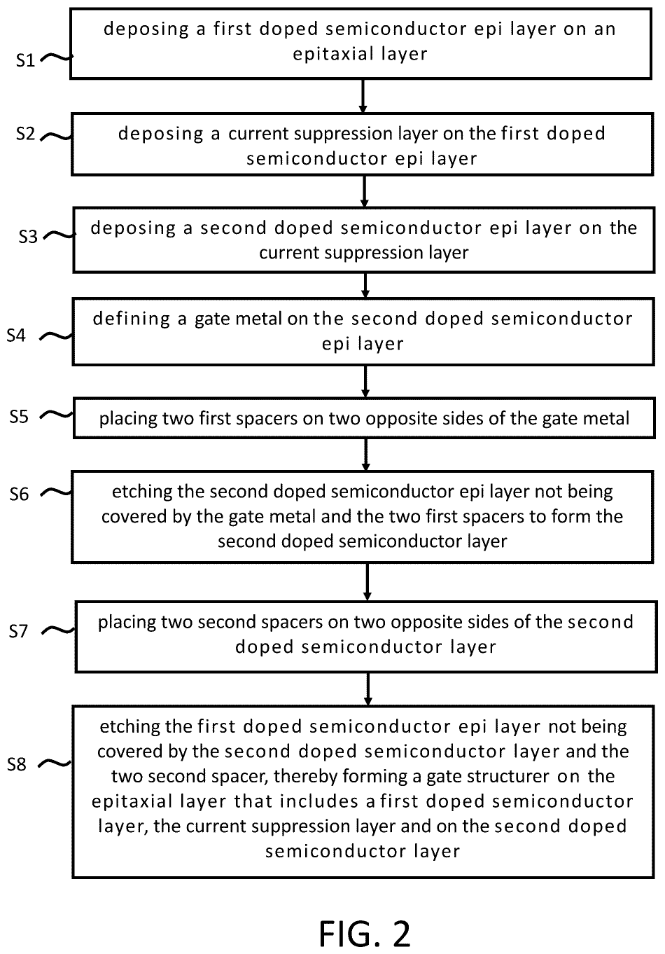

Please also refer to FIG. 2, FIG. 3A, and FIG. 3E for the flowchart of the high electron mobility transistor manufacturing method of the first embodiment of the present discourse, and for the schematic diagram of the process for manufacturing the first embodiment of the high electron mobility transistor using the high electron mobility transistor manufacturing method of the first embodiment. As shown in FIG. 2, the high electron mobility transistor manufacturing method of the present discourse includes Step S1 to Step S8.

Step S1: deposing a first doped semiconductor epi layer on an epitaxial layer.

As shown in FIG. 3A, the method includes deposing the first doped semiconductor epi layer 91 on the epitaxial layer 10. The first doped semiconductor epi layer 91 on the epitaxial layer 10 is a p-type GaN, and the p-type doped material is, for example, magnesium (Mg). Meanwhile, according to one embodiment of the present disclosure, the epitaxial layer 10 includes a substrate, a channel layer and a barrier layer. The substrate can be made of silicon, sapphire, SiC, diamond, or other composite materials such as silicon on insulator (SOI) substrate or a QST substrate. The channel layer is gallium nitride (GaN). The barrier layer can be made of an aluminum gallium nitride (AlyGa1-yN) structure.

Step S2: deposing a current suppression layer on the first doped semiconductor epi layer.

As shown in FIG. 3A, in this embodiment, the material of the current suppression layer 92 deposing on the first doped semiconductor epi layer 91 can be gallium nitride (AlGaN), a gallium nitride heterostructure (Al_{X}Ga_{1-X}N), where 0.4≤X≤1, or doped with p-type, n-type, or is undoped (i-type) atoms. In the preferred embodiment, the current suppression layer 92 is doped with p-type material, and the thickness of the current suppression layer 92 ranges from 0.5 nm to 5 nm.

Step S3: deposing a second doped semiconductor epi layer on the current suppression layer.

As shown in FIG. 3A, similar to the first doped semiconductor epi layer 91, the second doped semiconductor layer epi layer 93 can also be p-type GaN and is deposited on top of the current suppression layer 92.

Step S4: defining a gate metal on the second doped semiconductor epi layer.

As shown in IG. 3A, in this embodiment, the gate metal 50 is titanium nitride (TiN) and is deposited on the second doped semiconductor epi layer 93.

Step S5: placing two first spacers on two opposite sides of the gate metal.

As shown in FIG. 3A and FIG. 3B, in this embodiment, two first spacers 61 and 61a are placed on the second doped semiconductor epi layer 93 and disposed on opposite sides of the gate metal 50. This arrangement defines the width of the second doped semiconductor layer 41 after etching. The current suppression layer 92 is used to define the height of the second doped semiconductor layer 41, wherein the second doped semiconductor layer 41 has a second step height (H2) in a range of 65 nm to 80 nm.

Step S6: etching the second doped semiconductor epi layer not being covered by the gate metal and the two first spacers to form a second doped semiconductor layer.

As shown in FIG. 3A and FIG. 3B, the embodiment of the present disclosure uses the gate metal 50 and the two first spacers 61 and 61a as masks to perform a dry etching process on the second doped semiconductor epi layer 93, thereby completing a self-aligned process. Specifically, dry etching is performed on the second doped semiconductor epi layer 93 that is not covered by the gate metal 50 and the two first spacers 61 and 61a, resulting in the formation of the second doped semiconductor layer 41. It is noted that, as shown in previous FIG. 1A, FIG. 1B and FIG. 1C, there is no residual current suppression layer 92 above the first doped semiconductor epi layer 91 in the present disclosure.

Step S7: placing two second spacers on two opposite sides of the second doped semiconductor layer.

As shown in FIG. 3C, the two second spacers 62 and 62a are placed on the first doped semiconductor epi layer 91 and located on opposite sides of the second doped semiconductor layer 41. This setup allows for using the second doped semiconductor layer 41 and the two second spacer 62, 62a as masks to perform a dry etching process on the first doped semiconductor epi layer 91.

Step S8: etching the first doped semiconductor epi layer not being covered by the second doped semiconductor layer and the two second spacer, thereby forming a gate structurer on the epitaxial layer that includes the first doped semiconductor layer, the current suppression layer and the second doped semiconductor layer.

As shown in FIG. 3D, dry etching is performed on the first doped semiconductor epi layer 91 that is not covered by the two second spacers 62 and 62a and the second doped semiconductor layer 41. This completes the self-aligned process and forms the first doped semiconductor layer 43. Subsequently, as shown in FIG. 3E, removing the two first spacers 61 and 61a, as well as the two second spacers 62 and 62a, results in the formation of the gate structure 40 of the first embodiment of the present disclosure. The gate structure 40 includes the first doped semiconductor layer 43, the current suppression layer 92, and the second doped semiconductor layer 41. The first doped semiconductor layer 43 has a first width (W1), the second doped semiconductor layer 41 has a second width (W2), and the current suppression layer 92 has a third width (W3), wherein W1>W2, W3=W2. According to one embodiments of the present disclosure, the first doped semiconductor layer 43 and the second doped semiconductor layer 41 can be rectangular or trapezoidal, with a narrower top surface and a wider bottom surface.

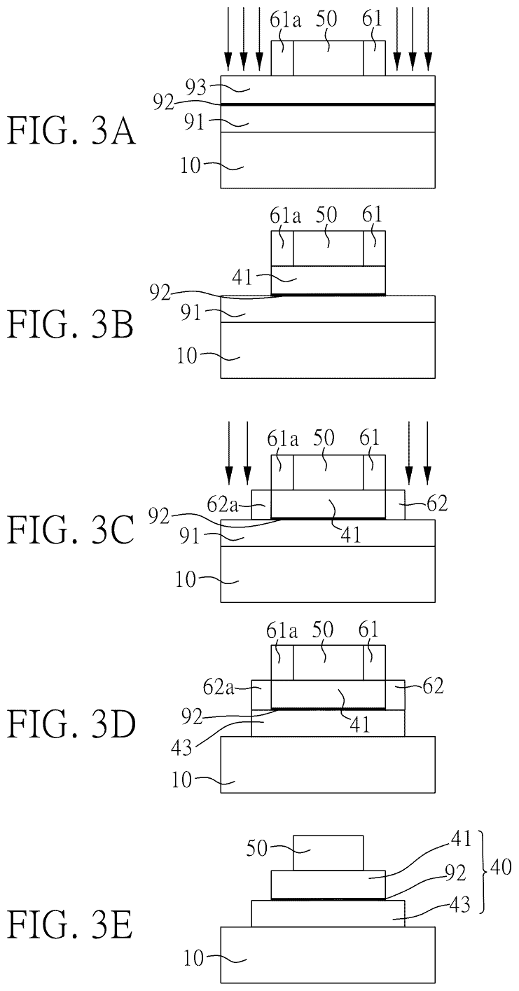

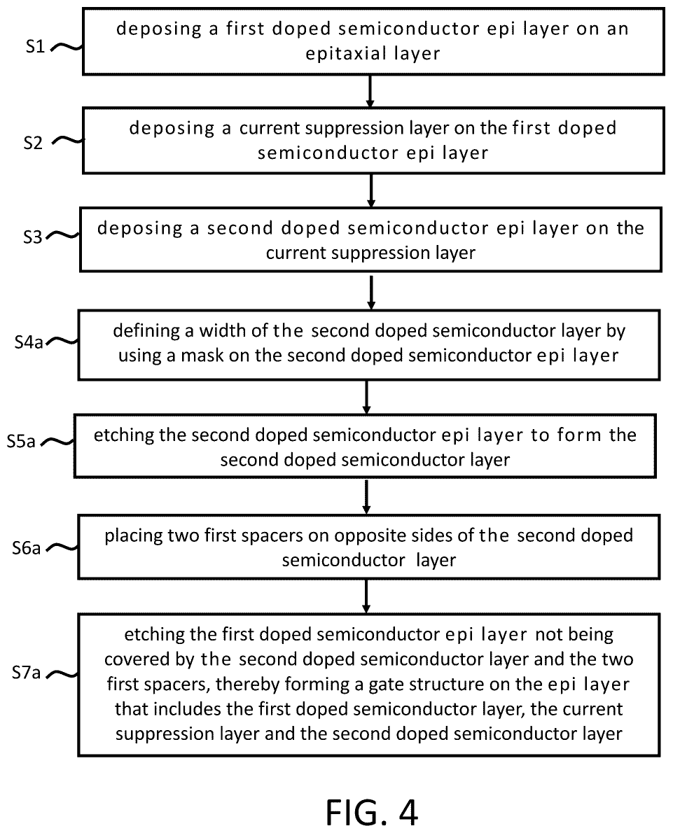

Please refer to FIG. 4, FIG. 5A and FIG. 5E for the flow chart of the second embodiment of the high electron mobility transistor manufacturing method, which describes using this method to manufacture the first embodiment of the high electron mobility transistor. As shown in FIG. 4, the second embodiment of the high electron mobility transistor manufacturing method of the present disclosure includes Step S1 to Step S3, Step S4a to Step S7a. The steps from Step S1 to Step S3 in the second embodiment are identical to those in the first embodiment. Additionally, Step S5a to Step S7a in the second embodiment correspond to Step S6 to Step S8 in the first embodiment. Therefore, these steps will not be repeated here; please refer to the relevant sections of the first embodiment.

As shown in FIG. 5A, the main difference between the manufacturing method of the second embodiment and that of the first embodiment is that in the second embodiment, a mask 80 is used to define the width of the second doped semiconductor layer 41 during the etching of the second doped semiconductor epi layer 93. The current suppression layer 92 is used to define the height of the second doped semiconductor layer 41. After the second doped semiconductor epi layer 93 is etched to form the second doped semiconductor layer 41, as shown in FIG. 5B to FIG. 5E, the manufacturing method of the second embodiment employs dry etching and self-aligning processes identical to Step S6 to Step S8 of the first embodiment. Consequently, the gate structure 40 of the first embodiment of the present disclosure as shown in FIG. 5E is formed. This gate structure 40 includes the first doped semiconductor layer 43, the current suppression layer 92, and the second doped semiconductor layer 41.

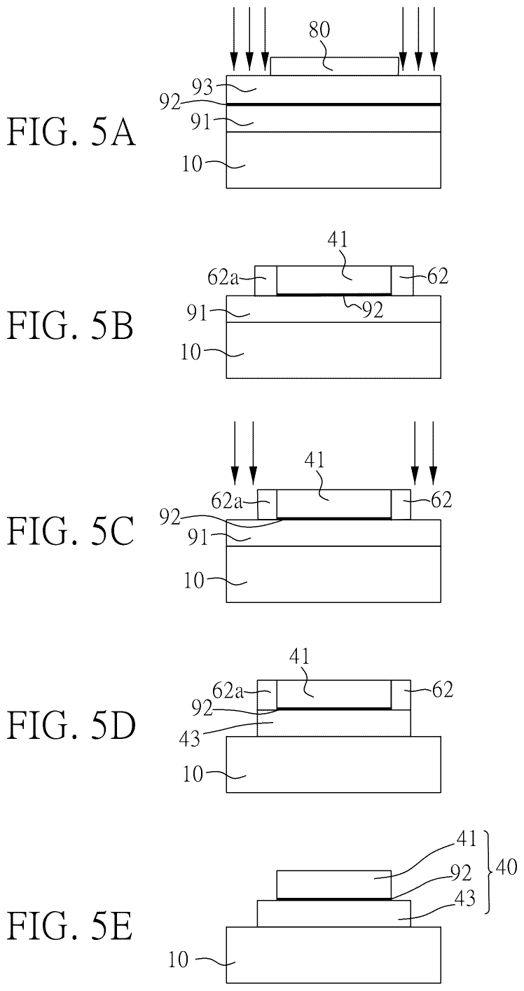

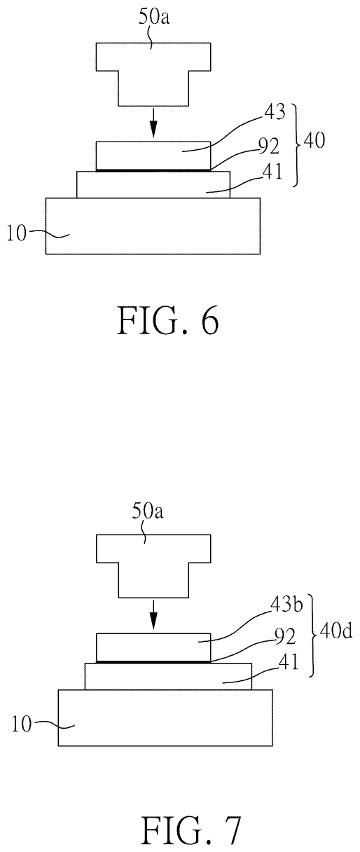

Please refer to FIG. 5E along with FIG. 6 and FIG. 7 for illustrations of the combination of the gate structure of the first embodiment of the present disclosure with gate metal in the second embodiment, and the combination of the gate structure from the fifth embodiment with gate metal in the second embodiment.

As shown in FIG. 6, since the manufacturing method of the second embodiment does not deposit gate metal beforehand, after completing the process outlined in the manufacturing method in the second embodiment, the gate structure 40 can be combined with the gate metal 50a. Moreover, the manufacturing method of the present disclosure, which uses a mask instead of spacers, allows for the creation of a gate structure 40d as shown in FIG. 7. The gate structure 40d can then be combined with the gate metal 50a.

By incorporating the current suppression layer 92, 92a, 92b, 92c into the gate structure 40, 40a, 40b, 40c, 40d of the high electron mobility transistor 1, la, 1b, 1c of the present disclosure, gate leakage current flowing from the gate metal in the vertical direction towards the second doped semiconductor layer 41, 41a, the current suppression layer 92, and the first doped semiconductor layer 43, 43a, 43b can be effectively reduced. Further, the etch depth (in the Z direction) of the second doped semiconductor layer 41, 41a and the first doped semiconductor layer 43, 43a, 43b of the stepped gate structure 40, 40a, 40b, 40c, 40d can be precisely controlled. This allows for lengthening the path for gate leakage current (Ig), thereby reducing the gate leakage current of the high electron mobility transistors 1, 1a, 1b, 1c. This approach addresses the issue found in prior art where controlling the etch depth of the gate structure was challenging, resulting in suboptimal gate structure shapes and ineffective suppression of gate leakage current.

It should be noted that many of the above-mentioned embodiments are given as examples for description, and the scope of the present invention should be limited to the scope of the following claims and not limited by the above embodiments.

What is claimed is:

1. A high electron mobility transistor (HEMT) comprising:
an epitaxial layer;
a source, disposed on the epitaxial layer;
a drain, disposed on the epitaxial layer;
a gate structure, disposed on the epitaxial layer and positioned between the source and the drain, the gate structure comprising a first doped semiconductor layer, a current suppression layer, and a second doped semiconductor layer, wherein the first doped semiconductor layer is disposed on the epitaxial layer, the current suppression layer is disposed on the first doped semiconductor layer, and the second doped semiconductor is disposed on the current suppression layer; and
a gate metal, disposed on the second doped semiconductor layer,
wherein the first doped semiconductor layer has a first width (W1), the second doped semiconductor layer has a second width (W2), and the current suppression layer has a third width (W3), wherein W1>W2, W3=W2.

2. The high electron mobility transistor as claimed in claim 1, wherein the gate metal has a fourth width (W4), wherein W2≥W4.

3. The high electron mobility transistor as claimed in claim 1, wherein a first step height (H1) of the first doped semiconductor layer being covered by the current suppression layer is greater than the first step height (H1′) of the first doped semiconductor layer not being covered by the current suppression layer.

4. The high electron mobility transistor as claimed in claim 1, wherein the first doped semiconductor layer comprises a first platform and the second doped semiconductor layer comprises a second platform, and the width of the second platform is less than or equal to the width of the first platform.

5. The high electron mobility transistor as claimed in claim 1, wherein the first doped semiconductor layer is in a trapezoidal shape.

6. The high electron mobility transistor as claimed in claim 1, wherein the first doped semiconductor layer has a first step height (H1) and the second doped semiconductor layer has a second step height (H2), wherein H2>H1.

7. The high electron mobility transistor as claimed in claim 6, wherein the second step height (H2) is ranged between 65 nm to 80 nm.

8. The high electron mobility transistor as claimed in claim 6, wherein the first step height (H1) is ranged between 5 nm to 20 nm.

9. The high electron mobility transistor as claimed in claim 6, wherein a thickness ratio of the second step height (H2) to the first step height (H1) is 13:4.

10. The high electron mobility transistor as claimed in claim 1, the gate structure has a gate height (H3), wherein H3≤120 nm.

11. The high electron mobility transistor as claimed in claim 1, wherein the first doped semiconductor layer and the second doped semiconductor layer have trapezoidal shapes.

12. The high electron mobility transistor as claimed in claim 1, wherein a thickness of the first doped semiconductor layer (H2) is smaller than 10 nm.

13. The high electron mobility transistor as claimed in claim 1, a thickness of the current suppression layer is ranged between 0.5 nm to 5 nm.

14. The high electron mobility transistor as claimed in claim 1, the current suppression layer is a gallium nitride heterostructure (Al_{X}Ga_{1-X}N), wherein 0.4≤X≤1.

15. The high electron mobility transistor as claimed in claim 1, the current suppression layer is doped with p-type, n-type, or is undoped (i-type) atoms.

16. A high electron mobility transistor manufacturing method comprising following steps:
deposing a first doped semiconductor epi layer on an epitaxial layer;
deposing a current suppression layer on the first doped semiconductor epi layer;
deposing a second doped semiconductor epi layer on the current suppression layer;
defining a gate metal on the second doped semiconductor epi layer;
placing two first spacers on two opposite sides of the gate metal;
etching the second doped semiconductor epi layer that is not covered by the gate metal and the two first spacers to form a second doped semiconductor layer;
placing two second spacers on two opposite sides of the second doped semiconductor layer; and
etching the first doped semiconductor epi layer that is not covered by the second doped semiconductor layer and the two second spacers, thereby forming a gate structurer on the epitaxial layer that includes a first doped semiconductor layer, the current suppression layer, and the second doped semiconductor layer, wherein the first doped semiconductor layer has a first width (W1), the second doped semiconductor layer has a second width (W2), and the current suppression layer has a third width (W3), wherein W1>W2, W3=W2.

17. The high electron mobility transistor manufacturing method as claimed in claim 16, wherein the gate structure has a gate height (H3), wherein H3≤120 nm.

18. The high electron mobility transistor manufacturing method as claimed in claim 16, wherein the current suppression layer is a gallium nitride heterostructure (Al_{X}Ga_{1-X}N), wherein 0.4≤X≤1.

19. The high electron mobility transistor manufacturing method as claimed in claim 16, a thickness of the current suppression layer is ranged between 0.5 nm to 5 nm.

20. A high electron mobility transistor manufacturing method comprising following steps:
deposing a first doped semiconductor epi layer on an epitaxial layer;
deposing a current suppression layer on the first doped semiconductor epi layer;
deposing a second doped semiconductor epi layer on the current suppression layer;
defining a width of a second doped semiconductor layer by using a mask on the second doped semiconductor epi layer;
etching the second doped semiconductor epi layer to form a second doped semiconductor layer;
placing two first spacers on opposite sides of the second doped semiconductor layer; and
etching the first doped semiconductor epi layer that is not covered by the second doped semiconductor layer and the two first spacers, thereby forming a gate structure on the epitaxial layer that includes a first doped semiconductor layer, the current suppression layer, and the second doped semiconductor layer, wherein the first doped semiconductor layer has a first width (W1), the second doped semiconductor layer has a second width (W2), and the current suppression layer has a third width (W3), wherein W1>W2, W3=W2.
